(19) United States
(12) Patent Application Publication
(10) Pub. No.: US 2026/0303039 A1
(43) Pub. Date: Oct. 1, 2026

(54) Systems and Methods for Intelligent Transimpedance Amplifiers

(71) Applicant: TeraSignal LLC, Newport Coast, CA (US)

(72) Inventors: Armond Hairapetian, Newport Coast, CA (US); Wim Cops, Newport Coast, CA (US)

(73) Assignee: TeraSignal LLC, Newport Coast, CA (US)

(21) Appl. No.: 19/578,202

(22) Filed: Mar. 25, 2026

Related U.S. Application Data
(60) Provisional application No. 63/777,601, filed on Mar. 25, 2025.

(51) Int. Cl. H03F 3/08; H03F 3/45; H03G 3/30

(52) U.S. Cl. CPC H03F 3/08; H03F 3/45; H03G 3/30

(57) ABSTRACT

One embodiment includes an intelligent TIA. The intelligent TIA includes a transimpedance amplifier capable of amplifying a received analog signal. The intelligent TIA includes a programmable linear equalizer capable of equalizing the amplified received analog signal to generate an equalized signal. The intelligent TIA includes a variable gain amplifier capable of amplifying the equalized signal to produce an amplified equalized signal. The intelligent TIA includes a line driver capable of generating an output signal based upon the amplified equalized signal. The intelligent TIA includes digital link adaptation circuitry capable of sampling the amplified equalized signal to produce a sampled signal, generating programming parameters for the programmable linear equalizer based upon the sampled signal, and programming the programmable linear equalizer.

### CROSS-REFERENCE TO RELATED APPLICATIONS

This application claims priority to U.S. Provisional Application No. 63/777,601, titled “Systems and Methods for Intelligent Transimpedance Amplifiers”, filed Mar. 25, 2025, which is hereby incorporated by reference in its entirety for all purposes.

### FIELD OF INVENTION

The present invention generally relates to optical communication systems, and more particularly to intelligent transimpedance amplifiers capable of performing digital diagnostics, adaptive equalization, and link training within optical receivers.

### BACKGROUND

Optical receivers are critical components in fiber-optic communication systems, responsible for converting optical signals transmitted over fiber or free-space channels into electrical signals for further processing. These receivers play an important role in enabling high-speed, long-distance, and low-latency data transmission across various communication networks. Optical receivers can detect and reconstruct transmitted data while minimizing signal degradation and noise interference. This process provides accurate delivery of digital and analog information in applications such as telecommunications, data centers, free-space optical (FSO) communication, and satellite communication systems.

An optical receiver is typically made up of several components that work together to accurately detect and process incoming signals. Optical receivers include a photodetector, which is typically a PIN photodiode or an Avalanche Photodiode (APD) that can convert optical signals into electrical currents. Because these currents are initially very weak, they pass through a preamplifier, often a transimpedance amplifier (TIA), which can amplify the signal while minimizing noise. To further refine and stabilize the signal, additional processing components such as filters, equalizers, decision circuits, and/or clock recovery systems help correct distortions and maintain synchronization. In more advanced optical systems, coherent optical receivers are used to capture both phase and amplitude information, greatly improving sensitivity and expanding data capacity, making them well suited for long-distance, high-speed optical communication.

The importance of optical receivers can extend beyond their role in signal detection, as they can impact the overall performance and efficiency of optical networks. Optical receiver sensitivity, or ability to detect weak signals, determines the maximum transmission distance of optical communication systems. Receivers with higher sensitivity allow for lower transmission power, reducing energy consumption and operational costs. Additionally, optical receivers influence bit error rates (BER), ensuring data integrity in high-speed networks. In advanced communication systems, such as Dense Wavelength Division Multiplexing (DWDM), sophisticated receivers enable efficient multiplexing of multiple data streams over a single optical fiber, enhancing network capacity and bandwidth.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

One embodiment includes an intelligent TIA. The intelligent TIA includes a transimpedance amplifier capable of amplifying a received analog signal. The intelligent TIA includes a programmable linear equalizer capable of equalizing the amplified received analog signal to generate an equalized signal. The intelligent TIA includes a variable gain amplifier capable of amplifying the equalized signal to produce an amplified equalized signal. The intelligent TIA includes a line driver capable of generating an output signal based upon the amplified equalized signal. The intelligent TIA includes digital link adaptation circuitry capable of sampling the amplified equalized signal to produce a sampled signal, generating programming parameters for the programmable linear equalizer based upon the sampled signal, and programming the programmable linear equalizer.

In another embodiment, the variable gain amplifier is a programmable variable gain amplifier. The digital link adaptation circuitry is further capable of generating programming parameters for the programmable variable gain amplifier based upon the sampled signal and programming the programmable variable gain amplifier.

In yet another embodiment, the digital link adaptation circuitry is further capable of generating programming parameters for a transmitter based upon the sampled signal and sending the programming parameters to the transmitter.

In a further embodiment, the digital link adaptation circuitry is further connected to a digital eye monitoring (DEM) circuitry, where the DEM circuitry is capable of output a DEM signal based upon the received analog signal.

One embodiment includes an optical receiver. The optical receiver includes a photodetector. The optical receiver includes an intelligent TIA in accordance with any of the TIAs of the preceding embodiments. The optical receiver includes a digital signal processor (DSP).

One embodiment includes a method for performing link training of a high speed serial link. The method includes sampling, at an optical receiver, an analog signal transmitted by a transmitter via a channel using an analog-to-digital converter, where the transmitted analog signal is a pulse. The method includes characterizing, at the optical receiver, the channel based upon the sampled analog signal. The method includes generating, at the optical receiver, parameters that are capable of being used by the transmitter to adjust the transmitted signal. The method includes transmitting, by the optical receiver, the generated parameters to the transmitter.

In another embodiment, the duration of the pulse is greater than a time required for transients caused by reflections of the pulse within the channel to have settled.

In yet another embodiment, the method further includes measuring a channel impulse response based upon the sampled analog signal and characterizing the channel based upon the sampled analog signal includes taking a derivative of the measured channel impulse response.

In a further embodiment, the parameters are capable of being used by the transmitter to program an equalizer within the transmitter.

In still another embodiment, the parameters are capable of being used by the transmitter to adjust a delay between signal components generated within the transmitter.

In an additional embodiment, the signal components are selected from the group consisting of: differential components; in-phase and quadrature components; and polarization components.

One embodiment includes a TIA. The intelligent TIA includes a transimpedance amplifier capable of amplifying a received analog signal. The intelligent TIA includes a programmable linear equalizer capable of equalizing the amplified received analog signal to generate an equalized signal. The intelligent TIA includes a variable gain amplifier capable of amplifying the equalized signal to produce an amplified equalized signal. The intelligent TIA includes a line driver capable of generating an output signal based upon the amplified equalized signal. The intelligent TIA includes diagnostic circuitry capable of sampling the amplified equalized signal to produce a sampled signal and producing a diagnostic output based upon the amplified equalized signal.

In another embodiment, the diagnostic circuitry includes a digital eye monitor circuit capable of producing a digital eye monitor signal.

In yet another embodiment, the diagnostic circuitry includes a digital eye monitor circuit capable of producing an estimated BER signal.

One embodiment includes a method of modifying an optical communication link. The method includes transmitting an optical signal from an optical transmitter to an optical receiver via an optical channel. The optical receiver includes an intelligent transimpedance amplifier and a digital signal processor. The intelligent transimpedance amplifier includes a transimpedance amplifier capable of amplifying a received analog signal, a programmable linear equalizer capable of equalizing the amplified received analog signal to generate an equalized signal, a variable gain amplifier capable of amplifying the equalized signal to produce an amplified equalized signal, a line driver capable of generating an output signal based upon the amplified equalized signal, and diagnostic circuitry capable of sampling the amplified equalized signal to produce a sampled signal and producing a diagnostic output based upon the amplified equalized signal. The method includes automatically monitoring the diagnostic output. The method includes determining that the optical receiver is defective based upon the monitored diagnostic output. The method includes replacing the optical receiver with a replacement optical receiver. The method includes transmitting a new optical signal from the optical transmitter to the replacement optical receiver via the optical channel.

In another embodiment, the diagnostic circuitry includes a digital eye monitor circuit capable of producing a digital eye monitor signal.

In a further embodiment, the diagnostic circuitry includes a digital eye monitor circuit capable of producing an estimated BER signal.

### BRIEF DESCRIPTION OF THE DRAWINGS

The description and claims will be more fully understood with reference to the following figures and data graphs, which are presented as exemplary embodiments of the invention and should not be construed as a complete recitation of the scope of the invention.

FIG. 1 illustrates a system diagram for optical transmission in accordance with an embodiment of the invention.

FIG. 2 illustrates a block diagram of an optical receiver incorporating an intelligent transimpedance amplifier in accordance with an embodiment of the invention.

FIG. 3A illustrates an intelligent transimpedance amplifier in accordance with an embodiment of the invention.

FIG. 3B illustrates an alternative intelligent TIA configuration in which microcontroller unit (MCU) outputs are provided to a digital-to-analog converter for generating an analog input to a polarization demultiplexer in accordance with an embodiment of the invention.

FIG. 3C illustrates an intelligent TIA configuration where MCU outputs are provided directly to upstream transmitters in accordance with an embodiment of the invention.

FIG. 3D illustrates a clock recovery unit that can be utilized within intelligent TIAs in accordance with an embodiment of the invention.

FIG. 4 illustrates a link training process that can be performed during an intelligent TIA setup mode in accordance with an embodiment of the invention.

FIG. 5 illustrates an iterative link training process that can be utilized by an intelligent TIA in a live or mission mode, in which live data is transmitted, in accordance with an embodiment of the invention.

FIGS. 6A-6B illustrate a comparison of signal quality before and after link training in accordance with an embodiment of the invention.

### DETAILED DESCRIPTION

Turning now to the drawings, intelligent TIAs capable of performing digital diagnostics and methods of performing digital diagnostics within optical receivers in accordance with various embodiments of the invention are illustrated. In many embodiments, intelligent TIAs are implemented to incorporate features such as (but not limited to) digital eye monitoring and/or adaptive equalization. In this way, intelligent TIAs can provide real-time link diagnostics in any class of linear optics including (but not limited to) Linear Receive Optics (LRO), Linear Pluggable Optics (LPO), On-Board Optics (OBO), Re-timed Receive Optics, Re-timed transmit optics, Fully Re-timed Optics, and Co-Packaged Optics). In several embodiments, the intelligent transimpedance amplifiers are capable of performing adaptive equalization in the optical receiver or perform link training and can communicate with upstream components including (but not limited to) optical transmitters to provide information that can be utilized to perform channel equalization.

Traditional pluggable optical modules contain an analog TIA followed by a digital signal processor (DSP) based re-timer at the receiver that performs adaptive equalization and diagnostic functions. To reduce the power in optical modules the DSP function is removed in the receiver creating a new class of linear optical receivers. Such linear optical receivers can be utilized within LPO, LRO, NPO and CPO modules. Without a DSP in the receiver it is typically regarded to be infeasible for analog TIAs to perform adaptive equalization or digital diagnostics. Systems and methods in accordance with many embodiments of the invention utilize an Intelligent TIA that is capable of performing adaptive equalization and digital diagnostics.

Optical receivers are used in a wide range of communication systems where high-speed, high-capacity data transmission is critical. Optical receivers can have important roles in fiber-optic networks, such as those used for internet backbones, data centers, and telecom infrastructures. During operation, optical receivers detect and convert the light signals traveling through optical fibers into electrical signals that digital systems can process. Optical receivers can accurately recover data from optical signals, even when those signals have been weakened, distorted, or degraded over long distances.

As data rates increase into the tens or hundreds of gigabits per second, the requirements for high-performance optical receivers have similarly grown, since even minor inaccuracies in signal interpretation at such speeds can lead to bit errors that reduce data integrity and compromise system performance. The emergence of Large Language Models (LLMs) has highlighted the importance of memory bandwidth and interconnect speed within computer systems as the number of parameters used by LLMs has increased at a rate that is orders of magnitude greater than the rate at which the memory bandwidth and interconnect speed of Graphics Processing Units (GPUs) has been increasing. Accordingly, interconnect latency can be critical to AI applications in a way that has not previously been the case in many of the other networking applications in which high-speed serial links have traditionally been utilized.

One way in which latency within an optical receiver can be reduced is to eliminate the use of a DSP in the receiver design. Eliminating the DSP can enable linear receive optics with lower overall power consumption, but this also removes traditional BER measurement tools. Receivers designed with fixed configurations may be poorly equipped to adapt to real-time transmission conditions. Moreover, current receivers typically lack built-in link monitoring features and may be unable to track key performance metrics, bit error rate, or signal-to-noise ratio, making it difficult to detect or respond to degradation.

To address these challenges, systems and methods in accordance with various embodiments provide an optical receiver module that incorporates digital eye monitoring and/or BER extraction directly within the TIA, enabling real-time link accountability without requiring a DSP-based receiver. Furthermore, TIAs in accordance with many embodiments of the invention can use information obtained through link monitoring to perform adaptive equalization.

In several embodiments, link monitoring allows the receiver to track metrics like optical power levels, bit error rate, and signal-to-noise ratio. With this data, network operators can detect early warning signs of performance degradation and take action before a failure occurs. In addition to link monitoring, link training can enable an optical receiver to provide information to a transmitter that can be utilized to configure the transmitter based upon information about the communication channel to improve the quality of transmitted signals at the receiver. When a connection is first established, link training can enable the receiver and transmitter to exchange information and adjust various transmission parameters to compensate for channel impairments. This process can compensate for factors such as fiber length, attenuation, or connection quality such that the receiver can “lock onto” the signal cleanly.

Optical communication systems that include optical receivers having intelligent TIAs and methods of performing link monitoring and/link training within optical receivers in accordance with various embodiments of the invention are discussed further below.

### Optical Communication Systems Incorporating Intelligent TIAs

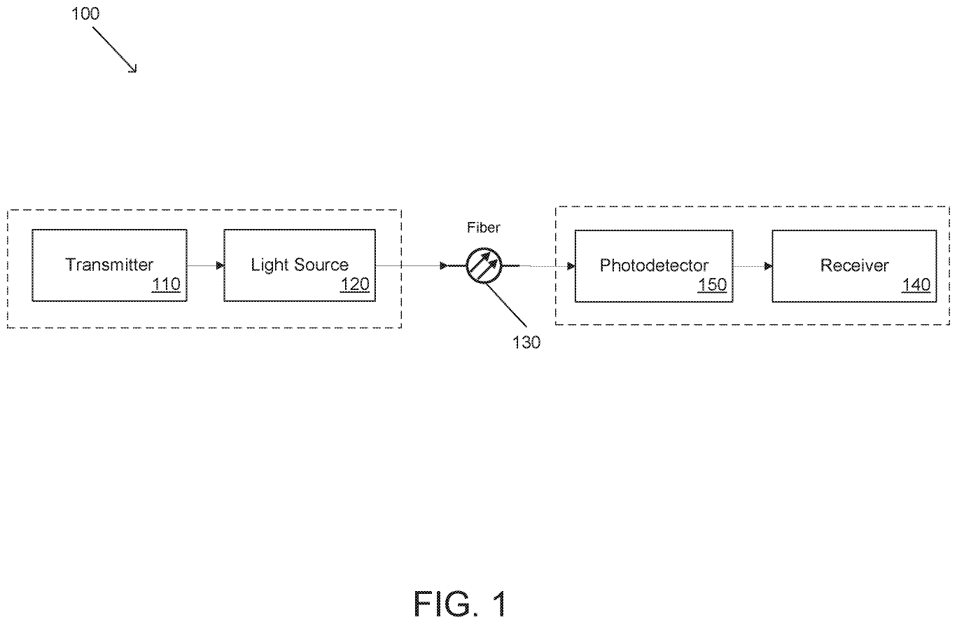

An optical communication, where the optical receiver incorporates an intelligent TIA, in accordance with an embodiment is illustrated in FIG. 1. System 100 includes an optical transmitter 110 incorporating an electrical-to-optical converter 120 (e.g. interferometric structures such as, but not limited to, a Mach-Zehnder modulator, or a directly modulated laser such as, but not limited to, a Vertical-Cavity Surface-Emitting laser). As the starting point in the system, optical transmitters in accordance with a number of embodiments convert electrical signals into optical signals that can be transmitted through a fiber 130. Optical transmitters typically include a light source, though in some embodiments, optical transmitters and light sources may be deployed as separate devices. In certain embodiments, light sources are high-power laser diodes that are capable of generating coherent, focused, and high-intensity light for high-performance applications. As can readily be appreciated, the specific light source that is utilized is largely dependent upon the requirements of specific applications.

System 100 further includes an optical receiver 140 incorporating a photodetector 150. The optical receiver is responsible for converting the incoming optical signal back into an electrical signal. In some embodiments, photodetectors and receivers may be packaged together as a single module. Photodetectors in accordance with various embodiments may be PIN photodiodes, which generate electrical current in response to the incoming light. This current can be amplified and processed to reconstruct the original data. As can be readily appreciated, the specific photodetector that is utilized and the manner in which the photodetector is packaged with the receiver electronics is largely dependent upon the requirements of specific applications.

While specific optical communication systems are described above with reference to FIG. 1, optical communication systems can be implemented using any of a variety of different configurations including alternative and/or additional components as appropriate to the requirements of specific applications in accordance with various embodiments of the invention. Optical receivers in accordance with various embodiments of the invention are discussed further below.

### Optical Receivers Incorporating Intelligent TIAs

As noted above, optical receivers in accordance with many embodiments of the invention can achieve improved (lower) latency by not utilizing a DSP to perform signal detection. In many embodiments of the invention, the optical receiver amplifies the received signal and uses a decision circuit to detect a transmitted symbol based upon the received and amplified analog signal. As can readily be appreciated, the performance of these low-latency optical receivers can be significantly impacted by channel impairments. Therefore, optical receivers in accordance with many embodiments of the invention incorporate circuitry that can be utilized to perform link monitoring and/or link training. In several embodiments, the optical receiver performs clock recovery based upon the transmitted analog signal to recover a sampling clock signal. The sampling clock signal can then be used to sample the received analog signal at a sampling rate that is typically significantly lower than the baud rate of the transmitted data signal. These digital samples can be provided to a processor such as (but not limited to) a microcontroller that can then utilize the digital signals to monitor the link. In this way, the optical receiver is able to digitally monitor the link while preserving the low latency of the analog signal path within the optical receiver. As is discussed below, the optical receiver can also utilize the link monitoring circuitry to characterize the channel.

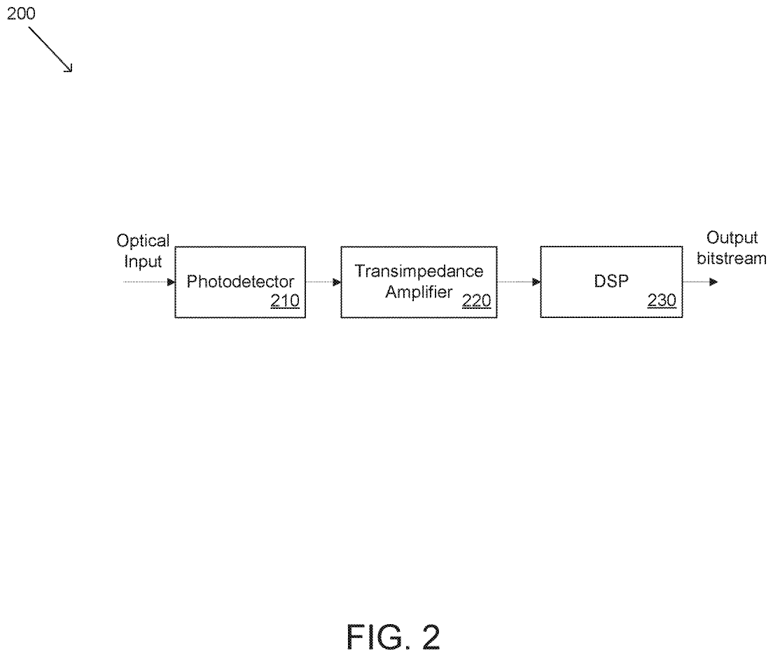

An optical receiver incorporating an intelligent TIA in accordance with an embodiment is illustrated in FIG. 2. The optical receiver 200 includes a photodetector 210, a TIA 220, and a DSP 230. The output of the photodetector 210 may be fed into the TIA, which serves to convert the small photocurrent into a usable voltage signal. In many embodiments, TIAs can be optimized for low noise and high bandwidth, allowing them to maintain signal integrity, especially in high-speed applications. As is discussed further below, intelligent TIAs in accordance with many embodiments of the invention are capable of sampling the signal in the analog signal path to provide diagnostic information regarding the performance of the intelligent TIA and/or adjust the configuration of the intelligent TIA to improve its performance. In several embodiments, the intelligent TIA includes a Digital Eye Monitor (DEM) that can provide diagnostic outputs including (but not limited to) a DEM signal and an estimated BER signal. The diagnostic outputs can be utilized to identify a source of errors within a link. As noted above, it can be challenging to locate a failing component within a communication link. The ability of intelligent TIAs to produce diagnostic outputs can greatly assist in the identification of a cause of degraded performance within a communication link. The DSP 230 is capable of sampling the output of the intelligent TIA using an analog-to-digital converter (ADC) and using the sampled output to reconstruct transmitted message bits. In many embodiments, the DSP performs Feed Forward Equalization and/or Decision Feedback Equalization. In fully retimed optics, the DSP can reside in the optical module. In linear receive optics, the DSP can reside in the serializer/deserializer (SERDES) of the host. As can readily be appreciated, the specific manner in which the optical receiver is implemented is largely dependent upon the requirements of specific applications.

While specific optical receivers are described above with reference to FIG. 2, optical receivers can be implemented using any of a variety of different configurations including alternative and/or additional components as appropriate to the requirements of specific applications in accordance with various embodiments of the invention.

### Intelligent TIAs

Intelligent TIAs include circuitry for sampling and analyzing the received analog signal in a manner that is independent of the signal path used for data detection. In many embodiments, sampling of the analog signal can be performed at a rate that is lower than the baud rate of the optical signal and the sampled information provided to an external processor for link monitoring and/or link training.

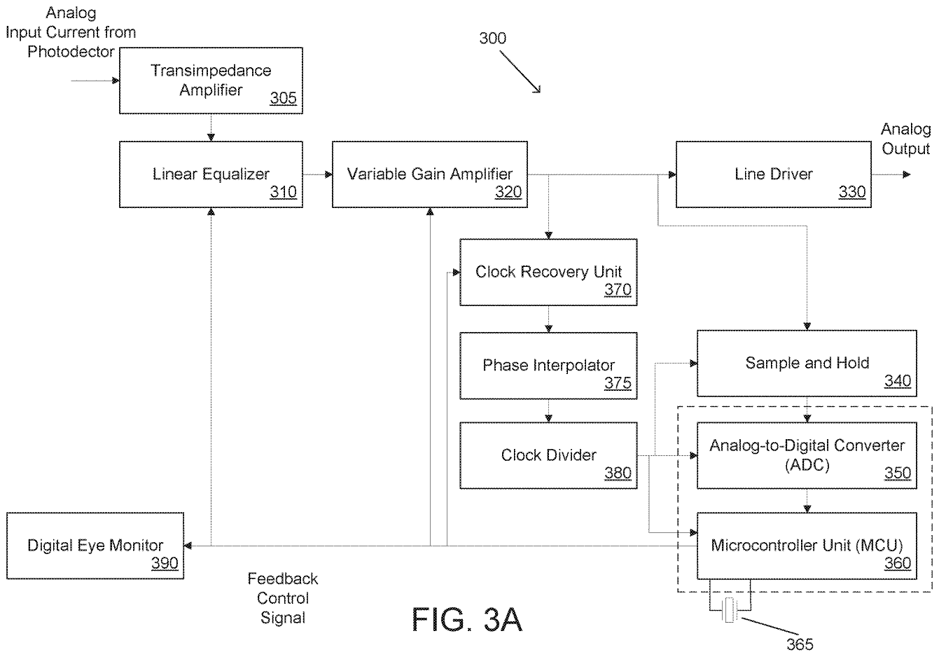

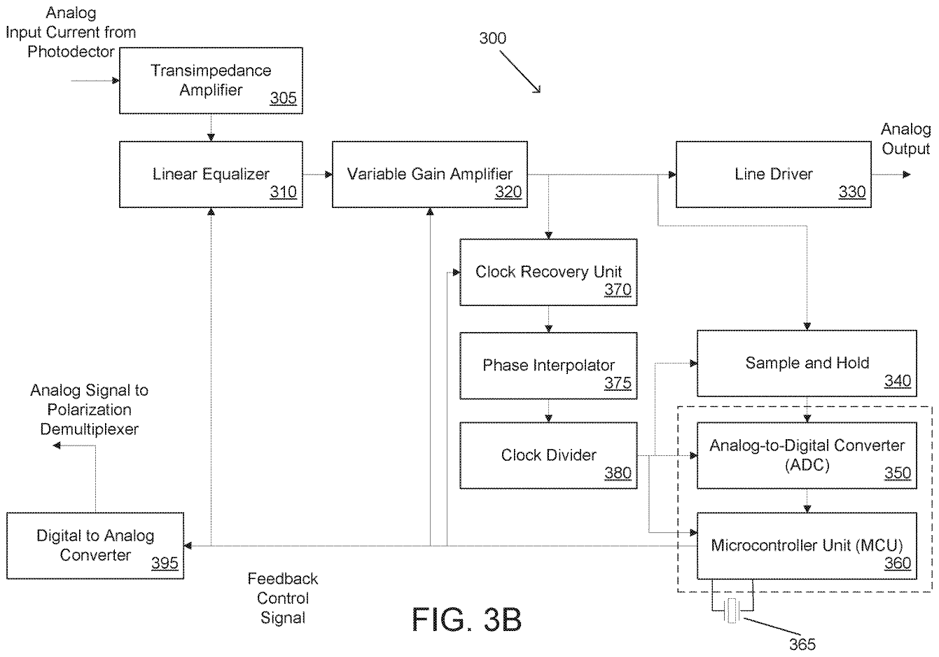

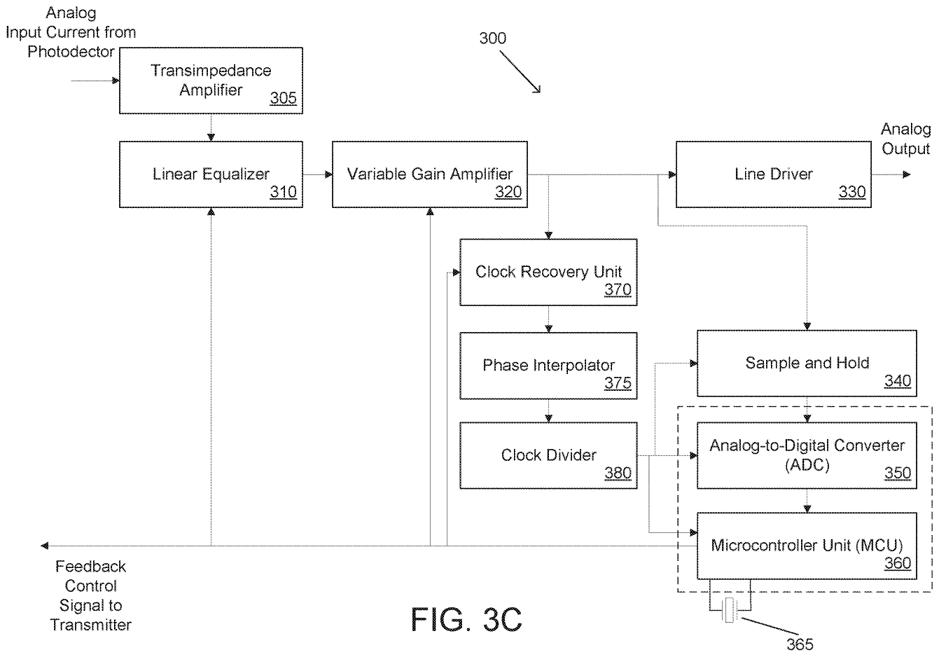

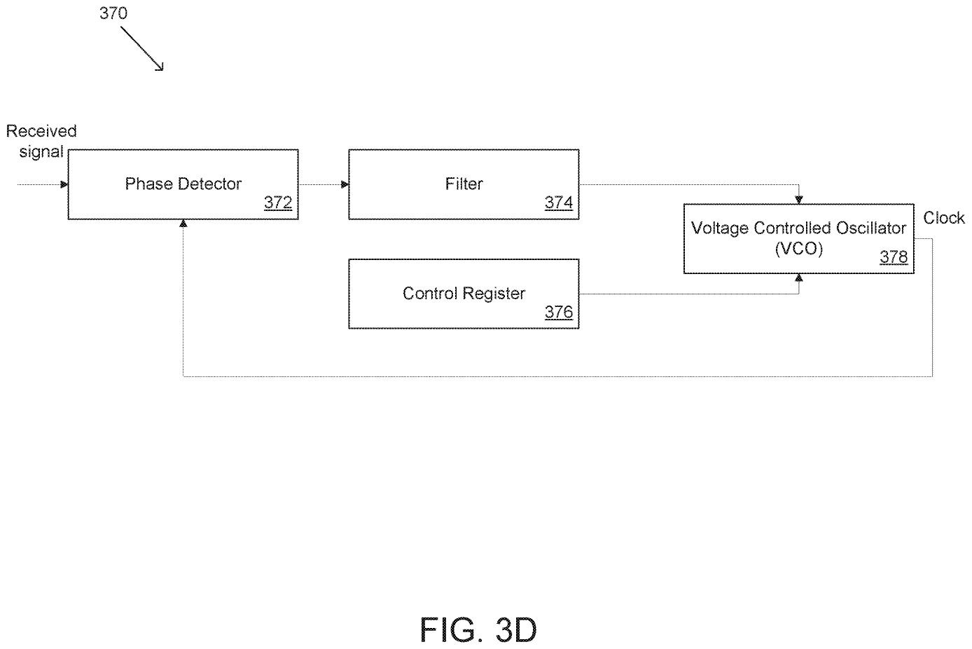

An intelligent TIA in accordance with an embodiment of the invention is illustrated in FIG. 3A. The intelligent TIA 300 includes a TIA 305, a programmable linear equalizer 310, a programmable variable gain amplifier 320, and a line driver 330. In the illustrated embodiment, the intelligent TIA 300 receives an analog input from a photodetector at the TIA 305 and utilizes the programmable linear equalizer 310 to provide an equalized output to the programmable variable gain amplifier 320. Programmable linear equalizers in accordance with some embodiments of the invention are implemented using a continuous time linear equalizer (CTLE) as well as using feed forward equalizer (FFE). The programmable variable gain amplifier 320 can adjust the gain of the signal that it receives in order to maintain a suitable signal amplitude at the input of the output driver 330. In the illustrated embodiment, the TIA 305, the linear equalizer 310, the variable gain amplifier 320, and the line driver 330 are shown as directly connected. As can readily be appreciated, additional analog components can be utilized to form a signal path, including a linear equalizer, a variable gain amplifier, and a line driver as appropriate to the requirements of specific intelligent TIA applications in accordance with various embodiments of the invention.

In many embodiments, intelligent TIAs also include components that enable digital link monitoring and/or adaptation. In the illustrated embodiment, the intelligent TIA 300 includes sample and hold circuitry 340, an ADC 350, and a microcontroller unit (MCU) 360 to enable the capture of digital samples of the signal within the signal path. The information captured by the MCU can be utilized to provide diagnostic information regarding the performance of the optical receiver and/or to program the programmable components within the analog signal path of the intelligent TIA including (but not limited to) the programmable linear equalizer 310, and the programmable variable gain amplifier 320. MCUs in accordance with a number of embodiments of the invention can provide outputs to a DEM 390, which can, in turn, generate diagnostic outputs such as (but not limited to) a DEM signal and/or an estimated BER. As noted above, diagnostic information can be invaluable to network operators in identifying the cause of an observed degradation in link performance. In many embodiments, the MCU can also communicate with the upstream transmitter (e.g. via a dedicated communication channel) and is capable of using information characterizing the channel to update the parameters utilized to configure the upstream transmitter.

As is discussed further below, the intelligent TIA can characterize the channel impulse response by sampling and digitizing a square wave slow clock signal. In the illustrated embodiment, the intelligent TIA further includes a clock recovery unit 370, a phase interpolator 380, and a clock divider 390 that can be configured to enable recovery of the sampling clock from the input data. In various embodiments, MCUs receive a sampling clock signal, sample, and hold the received analog signal. MCUs can utilize the information gained from sampling the received analog signal to provide instructions to the local equalizer to generate higher quality signals. While the TIA shown in FIG. 3A includes a clock recovery unit, Intelligent TIAs in accordance with many embodiments of the invention can receive an external clock source from sources such as (but not limited to) a clock signal provided by the transmitter via a clock forwarding interface.

An intelligent TIA in accordance with another embodiment of the invention is illustrated in FIG. 3B. In the illustrated embodiment, the MCU provides outputs to a digital-to-analog (DAC) converter 395. The DAC can provide analog signals to a polarization demultiplexer to enable dual polarization (DP) that can double data rate per wavelength. Dual polarization can be utilized in systems that employ modulation schemes including (but not limited to) DP-QAM, DP-CO-OFDM, and DP intensity modulation direct detection (IMDD). As can be readily appreciated, intelligent TIAs in accordance with several embodiments of the invention can include configurable circuitry enabling clock recovery from either the signal path or a neighboring channel as appropriate to the requirements of specific applications.

An intelligent TIA configuration where MCU outputs are provided directly to upstream transmitters in accordance with an embodiment of the invention is illustrated in FIG. 3C. In many embodiments, the transmitter signals can be adjusted to provide the optimum optical power, optimum transmit equalization and optimum linearity to result in lowest BER at the receiver.

In several embodiments, the MCU of an intelligent TIA is capable of scanning and sampling the signal inside the receiver during normal operation. In this way, the MCU can provide for a more traditional signal capture (e.g. digital eye monitoring). Using digital eye monitoring, the MCU can enable analysis during a live or mission mode with actual data patterns. In addition, the MCU can enable system testing with stress test patterns. In many embodiments, DEMs monitor the eye graphs of transmitted signals, and (manual) adjustments can be made to programmable components to minimize impairments, including (but not limited to) inter-symbol interference (ISI). DEMs in accordance with several embodiments of the invention can be configured by the MCU to perform monitoring when needed and with respect to a variety of signals including (but not limited to) NRZ, PAM4 and higher order PAM signals. In several embodiments, if the forward error correction (FEC) error goes beyond an acceptable limit, an intelligent TIA can report eye statistics captured using a DEM. This can enable the intelligent TIA to provide link accountability to an operator and help locate the components in the link (e.g. laser, fiber, etc.) that may be responsible for the excess error rate.

As noted above, intelligent TIAs in accordance with various embodiments of the invention, including (but not limited to) intelligent TIAs similar to those described above with respect to FIGS. 3A-3C, can be implemented on a single integrated circuit or using multiple integrated circuits. In many embodiments, an intelligent TIA integrated circuit component is implemented that provides an analog output for digitizing by an external ADC and processing of the digitized signal by an external MCU. In several embodiments, multiple intelligent TIAs share an MCU.

Intelligent TIAs in accordance with several embodiments of the invention, including (but not limited to) intelligent TIAs similar to those described above with respect to FIGS. 3A-3C, can be implemented using a 22 nm FDSOI CMOS process using high-speed analog/mixed-signal design techniques. Intelligent TIAs implemented using these processes can achieve 50% lower power consumption and smaller size than equivalent SiGe processes.

In several of the embodiments described above, the intelligent TIA characterizes the channel response by receiving and sampling a clock signal transmitted by the up-stream device (see e.g. FIGS. 3A-3C). In a number of embodiments, the MCU is capable of providing control signals to a voltage controlled oscillator (VCO) within the clock recovery unit of the intelligent TIA to frequency lock the VCO to a reference signal. In many embodiments, the reference signal is a signal generated by a stable source such as (but not limited to) a crystal oscillator. Once the VCO is frequency-locked, the clock recovery unit can then phase-lock the VCO based on the channel response using a phase lock loop (PLL). In this way, the output of the VCO can be used to generate a sampling clock signal. In a number of embodiments, the sampling clock signal has a frequency that is sufficiently high to oversample pulses transmitted during link training. As discussed above, during normal mode (data communication mode) the sampling clock signal has a frequency that is lower than the symbol rate of the transmitted data so that the transmitted data signal is under sampled by the intelligent TIA.

Components of the intelligent TIA may be integrated into a first component except for the ADC 350, the MCU 360 and a crystal oscillator 365. The ADC 350 and MCU 360 can be integrated into a second component that is connected via various connections to the first integrated component. The crystal oscillator 365 is also connected to the second component and provides a stable clock signal to the MCU 360.

In the illustrated embodiments, the clock recovery unit 370 includes a voltage-controlled oscillator that can be controlled by input signals received from the MCU 360. The MCU 360 can utilize the clock signal provided by the crystal oscillator 365 to generate a reference signal. In certain embodiments, the MCU 360 utilizes a divider to divide the clock signal received from the crystal oscillator 365 to generate the reference signal. The MCU can compare the clock signal output by the clock divider 390 to the reference signal and, based upon the comparison, provide input signals to the clock recovery unit 370 that can be utilized to control the frequency of the VCO. In a number of embodiments, the MCU can provide inputs to the clock recovery unit 370 that increase, decrease, or hold steady the frequency of the VCO.

A clock recovery unit that can be utilized within intelligent TIAs (including but not limited to the intelligent TIA of FIGS. 3A-C) in accordance with an embodiment of the invention is illustrated in FIG. 3D. The clock recovery unit 370 includes a phase detector 372, a filter 374, a control register 376, and a voltage controlled oscillator 378. As discussed above, an MCU can provide control signals to the clock recovery unit that cause the VCO to lock to a stable reference frequency that is very close to the reference frequency of the signal received via the channel. The clock recovery unit utilizes the received control signals to adjust the frequency of the VCO by altering the value stored within the control register 376. The components of the clock recovery unit 370 implement a PLL that causes the frequency-locked output of the VCO to lock to the phase of the received signal. In this way, the clock recovery unit 370 is able to recover a sampling clock signal from the signal received by the intelligent TIA via the channel.

While specific clock recovery units in accordance with various embodiments of the invention are described above with reference to FIG. 3D, clock recovery units can be implemented using any of a variety of different configurations including alternative and/or additional components to recover a clock signal from signals received by the intelligent TIA via the channel as appropriate to the requirements of specific applications in accordance with various embodiments of the invention.

While specific intelligent TIAs for low latency communication in accordance with various embodiments of the invention are described above with reference to FIGS. 3A-3D, intelligent TIAs can be implemented using any of a variety of different configurations including alternative and/or additional components to provide an analog signal path and the ability to perform digital link adaptation as appropriate to the requirements of specific applications in accordance with various embodiments of the invention.

### Link Training and Monitoring Processes

HSIs that incorporate receivers having intelligent TIAs in accordance with many embodiments of the invention can undergo link training to adjust for the channel impairments that may be detected. While much of the discussion that follows focuses on the use of link training in the context of intelligent TIAs, similar link training processes can also be utilized within a variety of receiver architectures including architectures that employ ADCs to receive transmitted symbols. The use of various link training processes that involve characterizing the channel and utilizing the channel characteristics to determine parameters for an equalizer within an upstream transmitter in accordance with various embodiments of the invention are discussed further below.

A communication channel can be characterized by its step or pulse response. High-speed serial links in accordance with various embodiments of the invention may include a transmitter capable of transmitting a periodic two-level signal to the intelligent TIA (receiver) for the digital link adaptation circuitry within the intelligent TIA to capture the channel response. This signal can be easily detected and used as a sampling clock by clock recovery circuitry within the intelligent TIA to digitize the channel response. By using a two-level signal with a low frequency over the channel-under-test, the sampling clock can be readily extracted, and the same signal can be used for digitizing the channel response. In many embodiments, the duration of the pulse that is utilized to characterize the channel is sufficiently long so that all of the transients associated with reflections within the channel have settled within the period of the pulse. In a number of embodiments, the receiver can completely characterize the channel by taking a derivative of the pulse response. As discussed further below, the channel response can then be utilized to determine parameters that the transmitter can utilize to reduce or eliminate ISI within the transmitted signal by pre-distorting the signal to compensate for channel distortion, thereby improving received signal quality.

Various embodiments capture channel responses caused by the transmission channel based upon the clock signal. In several embodiments, a clock recovery unit, a phase interpolator, and a clock divider (similar to those described above with respect to FIGS. 3A-3C) may be utilized in combination to recover a sampling clock. In certain embodiments, a clock signal can be received by the intelligent TIA via a synchronous clock source or a synchronous neighboring channel. In accordance with many embodiments, the digital link adaptation circuitry of the intelligent TIA can be configured to vary the sampling phase of the sampling clock such that a “scan” can be performed. As can readily be appreciated, the specific manner in which the intelligent TIA uses the recovered sampling clock to sample and analyze the channel characteristics is largely dependent upon the requirements of specific applications. In many embodiments, a clock signal is chosen such that the half-period of the clock signal is sufficiently long so that it is equal to or greater than the time required for all transients caused by reflections within the channel to have settled.

In various embodiments, systems and methods derive deterministic information regarding the transmission channel based on the captured impulse responses. When signals of pseudorandom binary sequences (PRBS) are sent, the transmission channel needs to be deconvolved to determine information related to channel characteristics, making the process computationally expensive. However, transmission channels may be more readily analyzed when it is only a pulse being sent. The impulse response of the channel, which completely characterizes the channel, can be obtained by taking the derivative of the pulse response. Deterministic information regarding the transmission channel obtained from the impulse response of the channel may be used to adjust the transmitter to equalize the transmission channel. Intelligent TIAs in accordance with several embodiments compute and set transmitter FFE and/or local Continuous Time Linear Equalization or local FFE coefficients to remove ISI caused by the channel and the components that are responsible for signal reflections. Many current SERDES implementations use FFEs with a small number of taps. When the number of taps in the FFE represents a time period that is shorter than the duration of the channel response, the intelligent TIA cannot completely eliminate ISI. However, characterizing the channel enables the intelligent TIA to cause the parameters of the taps in the FFE to be set in a manner that effectively reduces ISI. In a number of embodiments, the intelligent TIA is utilized in combination with a transmitter, where the SERDES has been implemented so that the FFE has a number of taps that corresponds to a time period that is equal to or greater than the duration of the channel response measured by the intelligent TIA.

In many embodiments, link training and channel equalization are implemented with minimal to no DSP-based components in the receiver signal path, which can lead to lowered power consumption as well as lower latency compared to DSP-based receivers. Unlike low-resolution ADCs such as 4-5-bit ENOB ADCs used in DSP-based receivers, intelligent TIAs in accordance with various embodiments can utilize a 12-bit ADC for link training and channel equalization, which results in more accurate transmitter FEE and CTLE settings. Link training and channel equalization processes in accordance with several embodiments of the invention greatly reduce the need for manual tuning of transmitters, making the intelligent TIA a plug-and-play solution for LROs. In selected embodiments, the amounts of channel equalizations can be enhanced by increasing the number of taps in the transmitter FFE. DEMs may be used to monitor the BER and adjust the CTLE setting during normal operations.

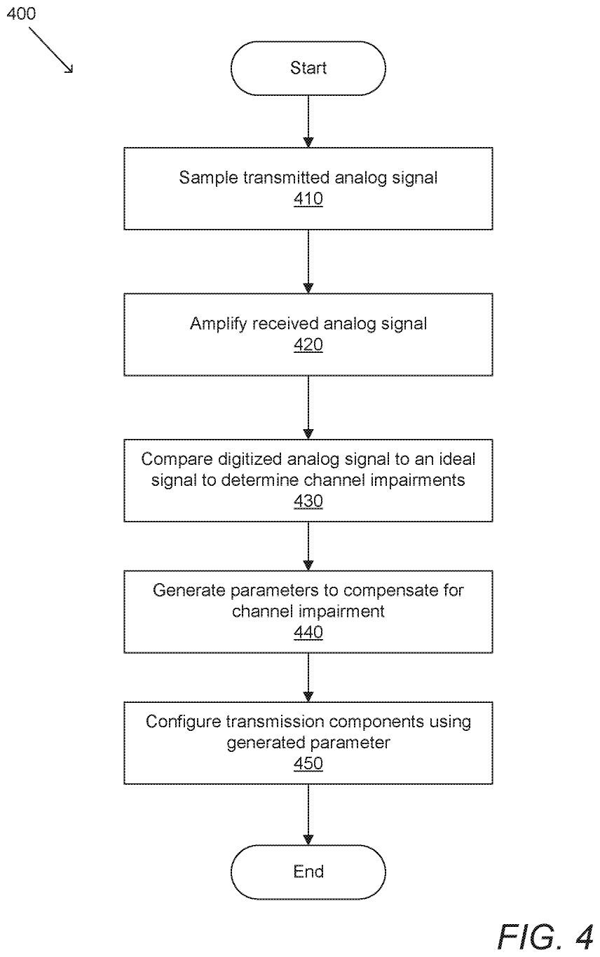

In certain embodiments, link training may be performed as part of a setup process at the start of an operation before any live traffic is communicated through the intelligent TIAs. A link training process that can be performed during an intelligent TIA setup mode in accordance with an embodiment of the invention is illustrated in FIG. 4. Process 400 samples (410) a transmitted analog signal. In many embodiments, the transmitted analog signal is sampled by an ADC that may be part of a single integrated circuit or implemented on a separate integrated circuit to the integrated circuit that performs the equalization of the analog signal within the intelligent TIA.

In many embodiments, the analog signal is transmitted through the channel to the receiver containing the intelligent TIA. In some embodiments, the transmitted analog signal may be a periodic unit pulse or a step. In many embodiments, initial pulses are utilized having widths that are long enough to characterize the channel but not so long as to materially increase setup time. As can readily be appreciated, the specific characteristics of the signal used to characterize the channel are largely dependent upon the requirements of specific applications. Process 400 amplifies (420) the received signal from the channel.

Process 400 compares (430) a digitized and amplified version of the sampled signal to an ideal signal and generates (440) a plurality of parameters that can be utilized to configure (450) the analog components of the intelligent TIA to compensate for the measured channel impairment. In several embodiments, an MCU is configured to determine the modifications to apply to the equalization settings in the transmitter and/or receiver based on the digitized amplified signal. In a number of embodiments, the MCU can set the FFE coefficients for the transmitter and/or parameters of the programmable analog components within the signal path of the intelligent TIA, including (but not limited to) the programmable linear equalizer and programmable variable gain amplifier. In several embodiments, the MCU can set the transmitter FFE coefficients using an interface such as (but not limited to) a CMIS interface to facilitate link training. Once the transmitter FFE coefficients have been set, the MCU can set the parameters utilized to configure the programmable components of the intelligent TIA's analog signal path (e.g. a programmable linear equalizer and/or a programmable variable gain amplifier) using a cost function. As can readily be appreciated, the specific components that are programmed by the MCU to perform link adaptation and/or the order in which specific components are programmed by the MCU are largely dependent upon the requirements of specific applications.

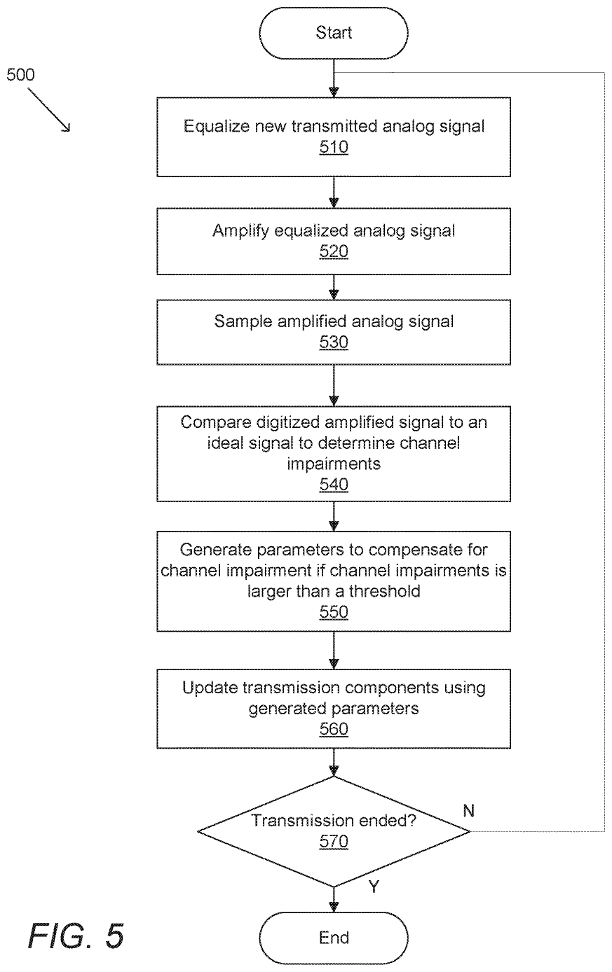

In some embodiments, link training may be performed as an iterative process, where the channel response with equalization is periodically compared to an ideal response in order to continuously update system parameters in response to changes in the observed channel impairments. FIG. 5 illustrates an iterative link training process that can be utilized by an intelligent TIA in a live or mission mode, in which live data is transmitted in accordance with an embodiment of the invention.

Process 500 equalizes (510) a newly transmitted analog signal and amplifies (520) the received analog signal. In several embodiments, transmitted analog signals are equalized using a linear equalizer on the intelligent TIA, which can address distortion incurred by the analog signal due to transmission through the channel.

Process 500 samples (530) the amplified analog signal and compares (540) the digitized amplified signal to an ideal signal to determine channel impairments. If the channel impairments are determined to exceed a threshold (or otherwise are determined to be out of a desired operating configuration), process 500 can generate (550) updated parameters to compensate for the observed channel impairments and utilize the updated parameters to update (560) the configuration of at least one analog component either within the upstream transmitter and/or within the signal path of the intelligent TIA. In several embodiments, the determined channel impairments may be reported to a user monitoring the transmission such that the user may exercise their own judgment in determining the proper compensation to the channel. User monitoring of link quality can be performed during live traffic without interfering with the transmission.

Process 500 determines (570) if additional optimization is required or the optimization process has otherwise ended. If the optimization process has not ended, process 500 can continue to monitor the transmitted analog signal and adjust the analog components of the intelligent TIA based upon updated parameters generated in response to observed channel impairments.

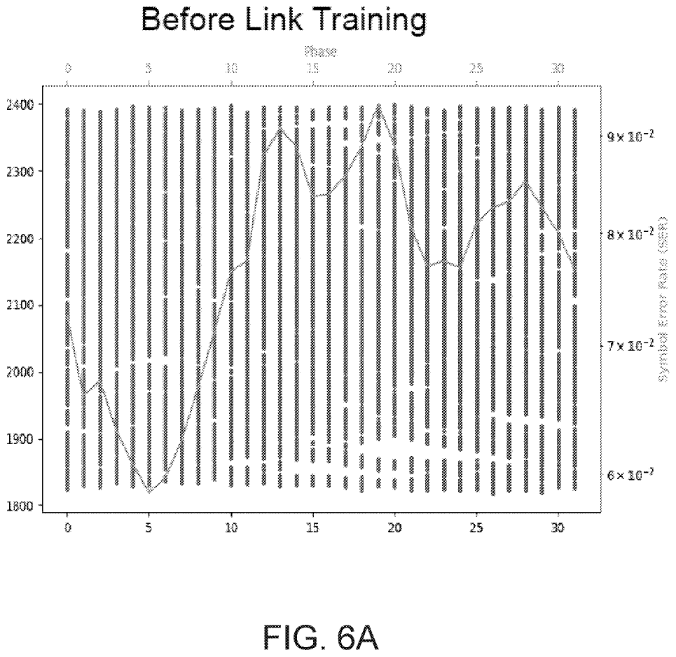

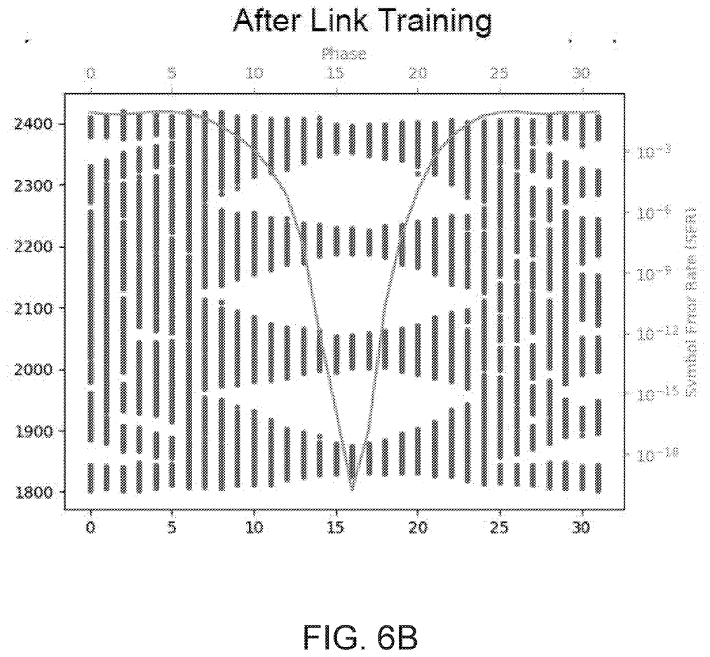

While specific processes are described above with reference to FIGS. 5 and 6, any of a variety of methods for link training in any of a variety of different intelligent TIA modes can be utilized as appropriate to the requirements of specific applications in accordance with various embodiments of the invention. For example, intelligent TIAs in accordance with many embodiments of the invention can be utilized over long distances in communication systems such as (but not limited to) optical communication systems. In a number of optical communication systems, intelligent TIAs can be utilized to characterize the optical channel response and to provide information via a feedback channel (e.g. a separate return path). Furthermore, the processes described above are not limited to performing link training utilizing intelligent TIAs but can also be implemented within re-timers in accordance with various embodiments of the invention. As noted above, the SERDES utilized in the transmitter may also be implemented so that the FFE of the SERDES has a number of taps corresponding to a time duration that is equal to or greater than the channel response duration measured by the re-timer. As can readily be appreciated, the specific manner in which link training is performed based upon the channel impulse response is largely only limited by the requirements of specific applications and the processes described herein for performing link training can be utilized within any of the systems disclosed above.

Monitoring HSIs can be important for ensuring reliable data transmission and maintaining optimal performance in computing, networking, and storage systems. Effective monitoring can prevent failures, enhance security, and enable proactive debugging for mission-critical applications. In many embodiments, systems and methods can monitor network traffic during mission mode. For example, network traffic may be monitored through eye diagrams and/or signal-to-noise ratios (SNR) of the transmission. Only when a deterioration in performance is detected does the analysis of the transmission channel begin to obtain deterministic information regarding the channel. Intelligent TIAs in accordance with many embodiments can be adjusted based on the deterministic information in a very short amount of time. In some embodiments, intelligent TIAs may terminate network traffic after performing channel equalization. Intelligent TIAs may behave like aSERDES and turn the transmitted signal into a digital signal such that the digital signal can be processed in the digital domain.

Simulations that provide an indication of the improvements in received signal quality that can be achieved using link training in accordance with an embodiment of the invention are illustrated in FIGS. 6A-B. As can be appreciated from FIG. 6B, the use of link training can result in digital eye diagrams in which the four signal levels of the PAM4 signal are more clearly differentiated after link training, indicating a stronger signal integrity. Conventional TIAs generally lack the capability to implement adaptive equalization and so are unable to achieve the improvements attainable by intelligent TIAs implemented in accordance with various embodiments of the invention.

While specific systems and methods incorporating intelligent TIAs are described above, the inventions described herein are not limited to any of the specific examples that are described. It is therefore to be understood that the present invention may be practiced in ways other than specifically described, without departing from the scope and spirit of the present invention. Thus, embodiments of the present invention should be considered in all respects as illustrative and not restrictive. Accordingly, the scope of the invention should be determined not by the embodiments illustrated, but by the appended claims and their equivalents.

What is claimed is:

1. An intelligent transimpedance amplifier (TIA) comprising:
a transimpedance amplifier capable of amplifying a received analog signal;
a programmable linear equalizer capable of equalizing the amplified received analog signal to generate an equalized signal;
a variable gain amplifier capable of amplifying the equalized signal to produce an amplified equalized signal;
a line driver capable of generating an output signal based upon the amplified equalized signal; and
digital link adaptation circuitry capable of:
sampling the amplified equalized signal to produce a sampled signal;
generating programming parameters for the programmable linear equalizer based upon the sampled signal; and
programming the programmable linear equalizer.

2. The intelligent TIA of claim 1, wherein:
the variable gain amplifier is a programmable variable gain amplifier; and
the digital link adaptation circuitry is further capable of:
generating programming parameters for the programmable variable gain amplifier based upon the sampled signal; and
programming the programmable variable gain amplifier.

3. The intelligent TIA of claim 1, wherein the digital link adaptation circuitry is further capable of:
generating programming parameters for a transmitter based upon the sampled signal; and
sending the programming parameters to the transmitter.

4. The intelligent TIA of claim 1, wherein the digital link adaptation circuitry is further connected to a digital eye monitoring (DEM) circuitry, where the DEM circuitry is capable of output a DEM signal based upon the received analog signal.

5. An optical receiver comprising:
a photodetector;
an intelligent TIA in accordance with any of the TIAs of claims 1 to 4; and
a digital signal processor (DSP).

6. A method for performing link training of a high speed serial link, the method comprising:
sampling, at an optical receiver, an analog signal transmitted by a transmitter via a channel using an analog-to-digital converter, where the transmitted analog signal is a pulse;
characterizing, at the optical receiver, the channel based upon the sampled analog signal;
generating, at the optical receiver, parameters that are capable of being used by the transmitter to adjust the transmitted signal; and
transmitting, by the optical receiver, the generated parameters to the transmitter.

7. The method of claim 6, wherein the duration of the pulse is greater than a time required for transients caused by reflections of the pulse within the channel to have settled.

8. The method of claim 7, further comprising:
measuring a channel impulse response based upon the sampled analog signal; and
characterizing the channel based upon the sampled analog signal comprises taking a derivative of the measured channel impulse response.

9. The method of claim 8, wherein the parameters are capable of being used by the transmitter to program an equalizer within the transmitter.

10. The method of claim 8, wherein the parameters are capable of being used by the transmitter to adjust a delay between signal components generated within the transmitter.

11. The method of claim 10, wherein the signal components are selected from the group consisting of:
differential components;
in-phase and quadrature components; and
polarization components.

12. An intelligent transimpedance amplifier (TIA) comprising:
a transimpedance amplifier capable of amplifying a received analog signal;
a programmable linear equalizer capable of equalizing the amplified received analog signal to generate an equalized signal;
a variable gain amplifier capable of amplifying the equalized signal to produce an amplified equalized signal;
a line driver capable of generating an output signal based upon the amplified equalized signal; and
diagnostic circuitry capable of:
sampling the amplified equalized signal to produce a sampled signal; and
producing a diagnostic output based upon the amplified equalized signal.

13. The intelligent TIA of claim 12, wherein the diagnostic circuitry comprises a digital eye monitor circuit capable of producing a digital eye monitor signal.

14. The intelligent TIA of claim 12, wherein the diagnostic circuitry comprises a digital eye monitor circuit capable of producing an estimated bit error rate (BER) signal.

15. A method of modifying an optical communication link comprising:
transmitting an optical signal from an optical transmitter to an optical receiver via an optical channel, where:
the optical receiver comprises an intelligent transimpedance amplifier and a digital signal processor:
the intelligent transimpedance amplifier comprises:
a transimpedance amplifier capable of amplifying a received analog signal;
a programmable linear equalizer capable of equalizing the amplified received analog signal to generate an equalized signal;
a variable gain amplifier capable of amplifying the equalized signal to produce an amplified equalized signal;
a line driver capable of generating an output signal based upon the amplified equalized signal; and
diagnostic circuitry capable of:
sampling the amplified equalized signal to produce a sampled signal; and
producing a diagnostic output based upon the amplified equalized signal;
automatically monitoring the diagnostic output;
determining that the optical receiver is defective based upon the monitored diagnostic output; and
replacing the optical receiver with a replacement optical receiver;
transmitting a new optical signal from the optical transmitter to the replacement optical receiver via the optical channel.

16. The method of claim 15, wherein the diagnostic circuitry comprises a digital eye monitor circuit capable of producing a digital eye monitor signal.

17. The method of claim 15, wherein the diagnostic circuitry comprises a digital eye monitor circuit capable of producing an estimated bit error rate (BER) signal.
